(19) United States
(12) Patent Application Publication
(10) Pub. No.: US 2025/0289082 A1
(43) Pub. Date: Sep. 18, 2025

(54) METHOD OF MANUFACTURING MASK ASSEMBLY

(71) Applicant: Samsung Display Co., Ltd., Yongin-si (KR)

(72) Inventors: Taekkyo Kang, Yongin-si (KR); Dosun Kim, Yongin-si (KR); Sanghoon Oh, Yongin-si (KR); Eugene Kang, Yongin-si (KR); Wonsu Choi, Yongin-si (KR)

(21) Appl. No.: 18/917,764

(22) Filed: Oct. 16, 2024

(30) Foreign Application Priority Data
Mar. 18, 2024 (KR) 10-2024-0037395

(51) Int. Cl. B23K 26/382; C23C 14/04

(52) U.S. Cl. CPC B23K 26/382; C23C 14/042

(57) ABSTRACT

A method of manufacturing a mask assembly includes fixing a mask sheet to a mask frame, wherein the mask sheet includes a sheet frame and a plurality of first deposition holes penetrating the sheet frame, and laser processing, by a laser processing apparatus, the plurality of first deposition holes into a plurality of mask deposition holes penetrating the sheet frame, respectively, wherein each of the plurality of first deposition holes includes a 1st-1 deposition hole in a first surface of the sheet frame, and a 1st-2 deposition hole in a second surface of the sheet frame opposite to the first surface and communicating with the 1st-1 deposition hole, wherein a width of each of the plurality of mask deposition holes gradually decreases from the first surface of the sheet frame toward the second surface of the sheet frame.

### CROSS-REFERENCE TO RELATED APPLICATION

The present application claims priority to and the benefit of Korean Patent Application No. 10-2024-0037395, filed on Mar. 18, 2024, in the Korean Intellectual Property Office, the entire disclosure of which is incorporated by reference herein.

### BACKGROUND

### 1. Field

One or more embodiments relate to a method, and more particularly, to a method of manufacturing a mask assembly.

### 2. Description of the Related Art

Mobile electronic devices have been widely used. In addition to small electronic devices such as mobile phones, tablet personal computers (PCs) have recently been widely used as mobile electronic devices.

In order to support various functions, such mobile electronic devices include a display device for providing a user with visual information, such as images and/or video. Recently, as other parts for driving the display device have become smaller, the proportion occupied by display devices in electronic devices has been gradually increasing, and a structure capable of being bent from a flat state to have a certain angle has also been developed.

### SUMMARY

One or more embodiments of the present disclosure provide a method for manufacturing a mask assembly for reducing a shadow phenomenon in a deposition process.

In addition, one or more embodiments of the present disclosure provide a method for manufacturing a mask assembly to reduce a phenomenon in which unnecessary deformation of the mask assembly occurs during the process of manufacturing the mask assembly.

However, the present disclosure is not limited thereto.

Aspects and features of embodiments of the present disclosure will be set forth in part in the description which follows and, in part, will be apparent from the description, or may be learned by practice of one or more embodiments of the present disclosure.

According to one or more embodiments, a method of manufacturing a mask assembly includes fixing a mask sheet to a mask frame, wherein the mask sheet includes a sheet frame and a plurality of first deposition holes penetrating the sheet frame, and laser processing, by a laser processing apparatus, the plurality of first deposition holes into a plurality of mask deposition holes penetrating the sheet frame, respectively, wherein each of the plurality of first deposition holes includes a 1st-1 deposition hole in a first surface of the sheet frame, and a 1st-2 deposition hole in a second surface of the sheet frame opposite to the first surface and communicating with the 1st-1 deposition hole, wherein a width of each of the plurality of mask deposition holes gradually decreases from the first surface of the sheet frame toward the second surface of the sheet frame.

A thickness of each of the plurality of mask deposition holes may be the same as a thickness of the sheet frame.

Each of the plurality of mask deposition holes may be concave from the first surface toward the second surface.

A width of the 1st-1 deposition hole may gradually decrease from the first surface of the sheet frame toward the second surface, and a width of the 1st-2 deposition hole may gradually decrease from the second surface of the sheet frame toward the first surface.

A sum of a thickness of the 1st-1 deposition hole and a thickness of the 1st-2 deposition hole may be equal to a thickness of the sheet frame.

The 1st-1 deposition hole may be concave from the first surface toward the second surface, and the 1st-2 deposition hole may be concave from the second surface toward the first surface.

In the fixing of the mask sheet to the mask frame, the sheet frame may include a bump protruding toward a central axis of the first deposition hole at a boundary between the 1st-1 deposition hole and the 1st-2 deposition hole.

The 1st-1 deposition hole may be thicker than the 1st-2 deposition hole.

The laser processing may include seating the mask sheet on a stage such that the second surface faces the stage, emitting, by a light source, a laser beam that passes through an optical unit and is incident on the first surface.

The light source may include at least one of a tuner, a beam splitter, a beam clipper, a scanner, or a telecentric F-θ lens.

According to one or more embodiments, a method of manufacturing a mask assembly includes fixing a mask sheet to a mask frame, wherein the mask sheet includes a sheet frame and a plurality of first deposition holes penetrating the sheet frame, and laser processing, by a laser processing apparatus, the plurality of first deposition holes into a plurality of mask deposition holes penetrating the sheet frame, respectively, wherein each of the plurality of first deposition holes includes a 1st-1 deposition hole in a first surface of the sheet frame, and a 1st-2 deposition hole in a second surface of the sheet frame opposite to the first surface and communicating with the 1st-1 deposition hole, wherein a width of the 1st-1 deposition hole gradually decreases from the first surface of the sheet frame toward the second surface, and a width of the 1st-2 deposition hole gradually decreases from the second surface of the sheet frame toward the first surface.

A sum of a thickness of the 1st-1 deposition hole and a thickness of the 1st-2 deposition hole may be equal to a thickness of the sheet frame.

The 1st-1 deposition hole may be concave from the first surface toward the second surface, and the 1st-2 deposition hole may be concave from the second surface toward the first surface.

In the fixing of the mask sheet to the mask frame, the sheet frame may include a bump protruding toward a central axis of the first deposition hole at a boundary between the 1st-1 deposition hole and the 1st-2 deposition hole.

A width of each of the plurality of mask deposition holes may gradually decrease from the first surface of the sheet frame toward the second surface.

A thickness of each of the plurality of mask deposition holes may be the same as a thickness of the sheet frame.

Each of the plurality of mask deposition holes may be concave from the first surface toward the second surface.

The 1st-1 deposition hole may be thicker than the 1st-2 deposition hole.

The laser processing may include seating the mask sheet on a stage such that the second surface faces the stage, emitting, by a light source, a laser beam that passes through an optical unit and is incident on the first surface.

The light source may include at least one of a tuner, a beam splitter, a beam clipper, a scanner, or a telecentric F-θ lens.

### BRIEF DESCRIPTION OF THE DRAWINGS

The above and other aspects and features of embodiments of the present disclosure will be more apparent from the following description taken in conjunction with the accompanying drawings, in which:

FIG. 1 is a cross-sectional view of an apparatus for manufacturing a display device, according to one or more embodiments;

FIG. 2 is a schematic flowchart of a method of manufacturing a mask assembly, according to one or more embodiments;

FIG. 3 is a schematic perspective view of a sheet frame according to one or more embodiments;

FIG. 4 is a schematic perspective view of a mask sheet according to one or more embodiments;

FIG. 5 is a schematic cross-sectional view of a mask sheet according to one or more embodiments;

FIG. 6 is an exploded perspective view of a mask assembly according to one or more embodiments;

FIG. 7 is a perspective view of a mask assembly according to one or more embodiments;

FIG. 8 is a schematic cross-sectional view of a mask sheet according to one or more embodiments;

FIG. 9 is a schematic perspective view of a laser processing apparatus according to one or more embodiments;

FIG. 10 is a schematic block diagram of an optical unit according to one or more embodiments;

FIG. 11 is a schematic plan view of a mask sheet according to one or more embodiments;

FIG. 12 is a schematic cross-sectional view of a mask sheet according to one or more embodiments;

FIG. 13 is a schematic cross-sectional view of a mask sheet according to one or more embodiments;

FIG. 14 is a schematic plan view of a display device according to one or more embodiments;

FIG. 15 is a schematic cross-sectional view of a display device according to one or more embodiments; and

FIG. 16 is an equivalent circuit diagram of a pixel according to one or more embodiments.

### DETAILED DESCRIPTION

Reference will now be made in detail to embodiments, examples of which are illustrated in the accompanying drawings, wherein like reference numerals refer to like elements throughout. In this regard, one or more embodiments may have different forms and should not be construed as being limited to the descriptions set forth herein. Accordingly, embodiments are merely described below, by referring to the figures, to explain aspects and features of embodiments of the present disclosure. As used herein, the term “and/or” includes any and all combinations of one or more of the associated listed items. As used herein, “A and/or B” represents the case of A, B, or A and B. Also, “at least one of A and B” represents the case of A, B, or A and B. Throughout the present disclosure, the expression “at least one of a, b or c” or “at least one of a, b, and c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects, aspects, and features of one or more embodiments and methods of accomplishing the same will become apparent from the following detailed description of the one or more embodiments, taken in conjunction with the accompanying drawings. However, one or more embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements may not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features and/or elements.

It will be further understood that, when a layer, region, or element is referred to as being on another layer, region, or element, it may be directly or indirectly on the other layer, region, and/or element. That is, for example, intervening layers, regions, and/or elements may be present.

Sizes of elements in the drawings may be exaggerated or reduced for convenience of explanation. For example, because sizes and thicknesses of elements in the drawings are arbitrarily illustrated for convenience of description, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time and/or performed in an order opposite to the described order.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

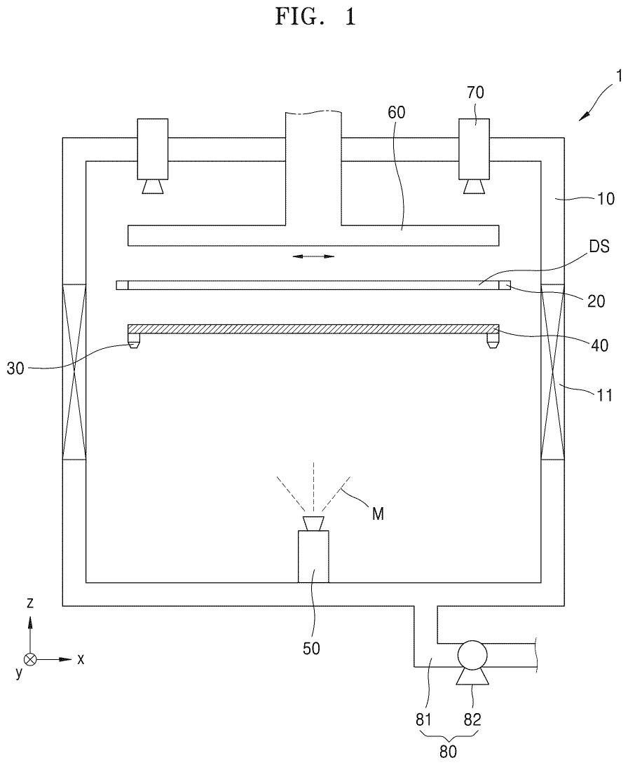

FIG. 1 is a cross-sectional view of an apparatus 1 for manufacturing a display device, according to one or more embodiments.

The apparatus 1 may include a chamber 10, a first support 20, a second support 30, a mask assembly 40, a deposition source 50, a magnetic force unit 60, a vision unit 70, and a pressure controller 80.

The chamber 10 may include a space therein and may accommodate a display substrate DS and the mask assembly 40. In this regard, a portion of the chamber 10 may be open, and a gate valve 11 may be installed in the open portion of the chamber 10. In this case, the open portion of the chamber 10 may be opened or closed according to an operation of the gate valve 11.

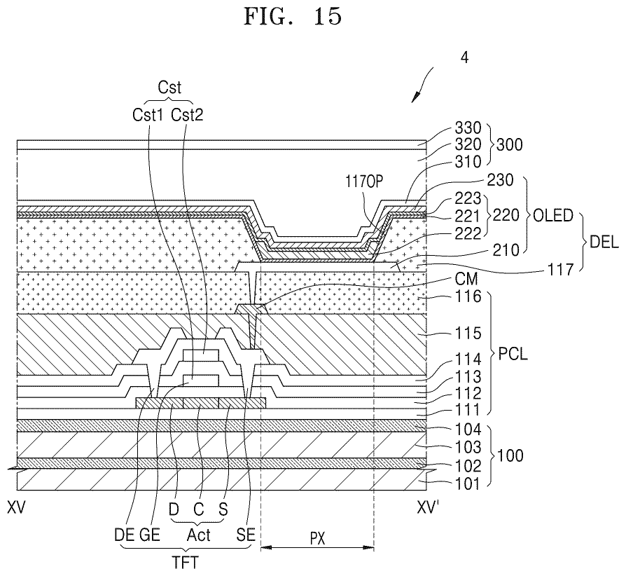

In this regard, the display substrate DS may refer to the display substrate DS in the process of manufacturing a display device, in which at least one of an organic layer, an inorganic layer, or a metal layer is deposited on a substrate 100 described below. Alternatively, the display substrate DS may be the substrate 100 (e.g., see FIG. 15) on which none of an organic layer, an inorganic layer, and a metal layer has been deposited yet.

The first support 20 may support the display substrate DS. In this regard, the first support 20 may be in the form of a plate fixed inside the chamber 10. In another embodiment, the first support 20 may have the display substrate DS seated thereon and may be in the form of a shuttle linearly moveable in the chamber 10. In another embodiment, the first support 20 may include an electrostatic chuck or adhesive chuck arranged in the chamber 10 to be fixed to the chamber 10 or movable in the chamber 10.

The second support 30 may support the mask assembly 40. In this regard, the second support 30 may be arranged inside the chamber 10. The second support 30 may fine-adjust a position of the mask assembly 40. In this regard, the second support 30 may include a separate driver and/or alignment unit for moving the mask assembly 40 in different directions.

In another embodiment, the second support 30 may be in the form of a shuttle. In this case, the second support 30 may have the mask assembly 40 seated thereon and may transport the mask assembly 40. For example, the second support 30 may move out of the chamber 10 to have the mask assembly 40 seated thereon and then may enter the chamber 10 from outside the chamber 10.

In the above case, the first support 20 and the second support 30 may be integrally formed with each other. In this case, the first support 20 and the second support 30 may include a movable shuttle. In this regard, the first support 20 and the second support 30 may include a structure of fixing the mask assembly 40 and the display substrate DS such that the display substrate DS is seated on the mask assembly 40, and may linearly move the display substrate DS and the mask assembly 40 concurrently (e.g., simultaneously).

However, a form in which the first support 20 and the second support 30 are distinct from each other and arranged at different positions and a form in which the first support 20 and the second support 30 are arranged inside the chamber 10 will be mainly described below for convenience.

The mask assembly 40 may be arranged inside the chamber 10 to face the display substrate DS. A deposition material M may pass through the mask assembly 40 and may be deposited on the display substrate DS.

The deposition source 50 may face the mask assembly 40, and may supply the deposition material M such that the deposition material M passes through a deposition area of the mask assembly 40 and is deposited on the display substrate DS. In this regard, the deposition source 50 may evaporate and/or sublimate the deposition material M by applying heat to the deposition material M. The deposition source 50 may be fixed inside the chamber 10 and/or may be arranged inside the chamber 10 to be linearly moveable in one direction.

The magnetic force unit 60 may be arranged inside the chamber 10 to face the display substrate DS and/or the mask assembly 40. In this regard, the magnetic force unit 60 may apply magnetic force to the mask assembly 40, thereby pressing the mask assembly 40 toward the display substrate DS. In particular, the magnetic force unit 60 may prevent or protect the mask assembly 40 from sagging down and may also cause the mask assembly 40 to be adjacent to the display substrate DS. In addition, the magnetic force unit 60 may maintain a uniform interval between the mask assembly 40 and the display substrate DS.

The vision unit 70 may be arranged in the chamber 10 and may capture images of positions of the display substrate DS and the mask assembly 40. In this regard, the vision unit 70 may include a camera for capturing images of the display substrate DS and the mask assembly 40. Based on the images captured by the vision unit 70, positions of the display substrate DS and the mask assembly 40 may be identified, and the mask assembly 40 may be checked for deformation. In addition, based on the images, a position of the display substrate DS may be fine-adjusted by the first support 20, and/or a position of the mask assembly 40 may be fine-adjusted by the second support 30. However, a case where the second support 30 fine-adjusts a position of the mask assembly 40 to align positions of the display substrate DS and the mask assembly 40 with each other will be mainly described below.

The pressure controller 80 may be connected to the chamber 10 to control the internal pressure of the chamber 10. For example, the pressure controller 80 may adjust the internal pressure of the chamber 10 to a level that is the same as or similar to that of atmospheric pressure. In addition, the pressure controller 80 may adjust the internal pressure of the chamber 10 to a level that is the same as or similar to that of a vacuum state.

The pressure controller 80 may include a connection pipe 81 connected to the chamber 10 and a pump 82 installed at the connection pipe 81. In this regard, depending on an operation of the pump 82, external air may flow in through the connection pipe 81 or gas inside the chamber 10 may be guided to the outside through the connection pipe 81.

According to a method of manufacturing a display device by using the apparatus 1 described above, the display substrate DS may be prepared first.

The pressure controller 80 may maintain the internal pressure of the chamber 10 at a level that is the same as or similar to that of atmospheric pressure, and the gate valve 11 may operate to open the open portion of the chamber 10.

After that, the display substrate DS may be loaded into the chamber 10 from outside the chamber 10. In this regard, the display substrate DS may be loaded into the chamber 10 in various ways. For example, the display substrate DS may be loaded into the chamber 10 from outside the chamber 10 through a robot arm, etc., arranged outside the chamber 10. In another embodiment, when the first support 20 is in the form of a shuttle, the first support 20 may be carried out of the chamber 10 from inside the chamber 10, and then, the display substrate DS may be seated on the first support 20 through a separate robot arm, etc., arranged outside the chamber 10, and the first support 20 may be loaded into the chamber 10 from outside the chamber 10.

As described above, the mask assembly 40 may be arranged inside the chamber 10. In another embodiment, in the same or similar manner as the display substrate DS, the mask assembly 40 may be loaded into the chamber 10 from outside the chamber 10.

When the display substrate DS is loaded into the chamber 10, the display substrate DS may be seated on the first support 20. In this regard, the vision unit 70 may capture images of positions of the display substrate DS and the mask assembly 40. Positions of the display substrate DS and the mask assembly 40 may be identified based on the images captured by the vision unit 70. In this regard, the apparatus 1 may include a separate controller to identify positions of the display substrate DS and the mask assembly 40.

Once positions of the display substrate DS and the mask assembly 40 are identified, the second support 30 may fine-adjust the position of the mask assembly 40.

After that, the deposition source 50 may operate to supply the deposition material M toward the mask assembly 40, and the deposition material M having passed through a plurality of pattern holes in the mask assembly 40 may be deposited on the display substrate DS. In this regard, the deposition source 50 may move parallel to the display substrate DS and the mask assembly 40, or the display substrate DS and the mask assembly 40 may move parallel to the deposition source 50. That is, the deposition source 50 may move relative to the display substrate DS and the mask assembly 40. In this regard, the pump 82 may suck in gas inside the chamber 10 and discharge the gas to the outside, thereby maintaining the internal pressure of the chamber 10 at a level that is the same as or similar to that of a vacuum state.

As described above, the deposition material M supplied from the deposition source 50 may pass through the mask assembly 40 and may be deposited on the display substrate DS, and accordingly, a plurality of layers that are stacked on a display device described below, for example, at least one of an organic layer, an inorganic layer, or a metal layer, may be formed.

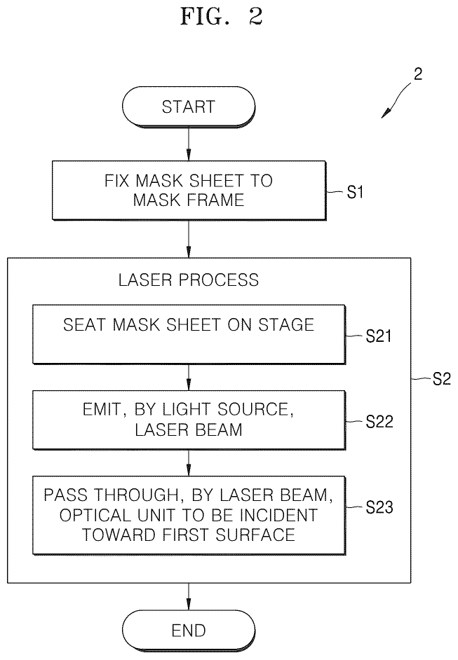

FIG. 2 is a schematic flowchart of a method 2 of manufacturing the mask assembly 40, according to one or more embodiments.

Referring to FIG. 2, the method 2 of manufacturing the mask assembly 40 may include an operation of fixing a mask sheet 42 to a mask frame 41 (in operation S1) and a laser processing operation (in operation S2).

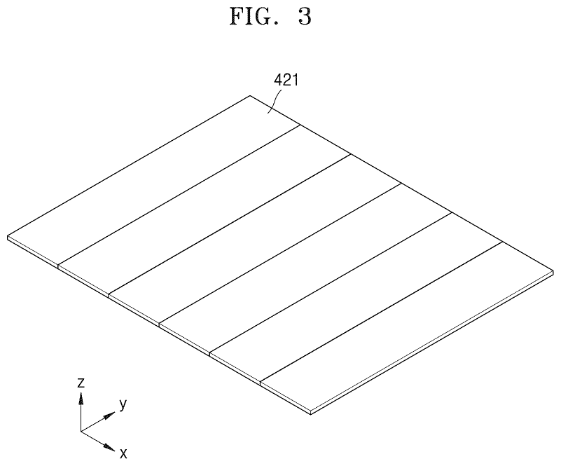

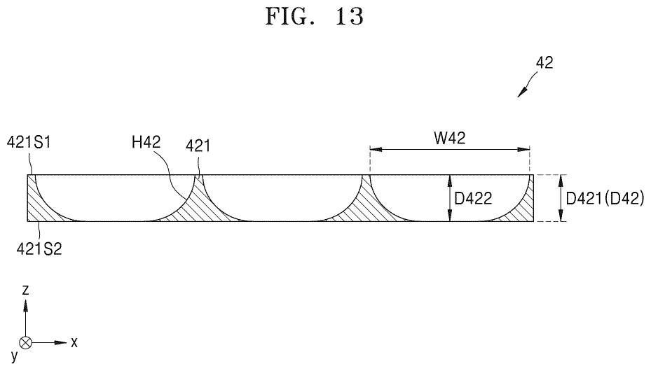

A detailed description of the method 2 of manufacturing the mask assembly 40 is given below with reference to FIGS. 3 and 13.

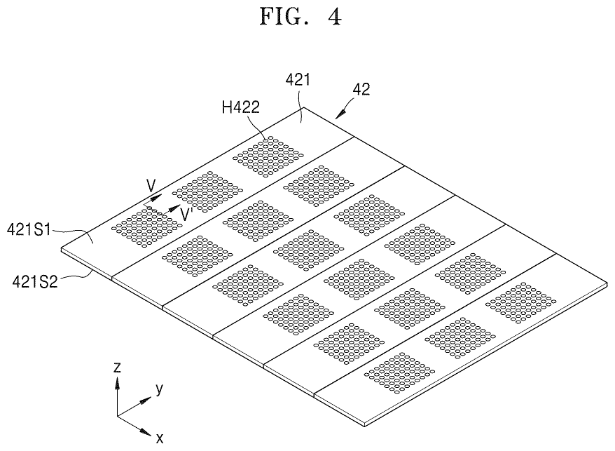

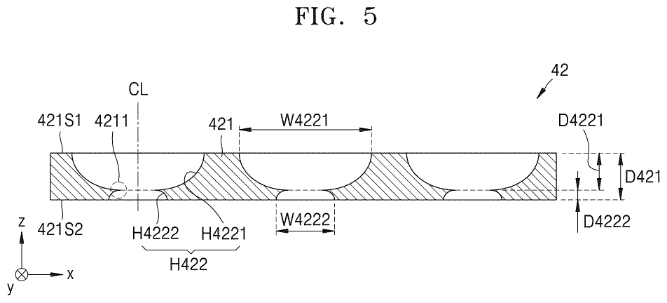

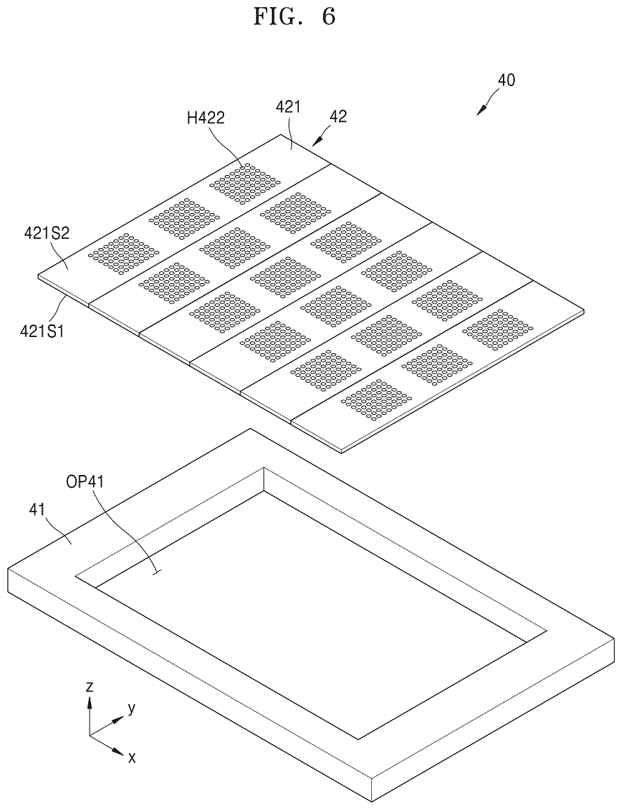

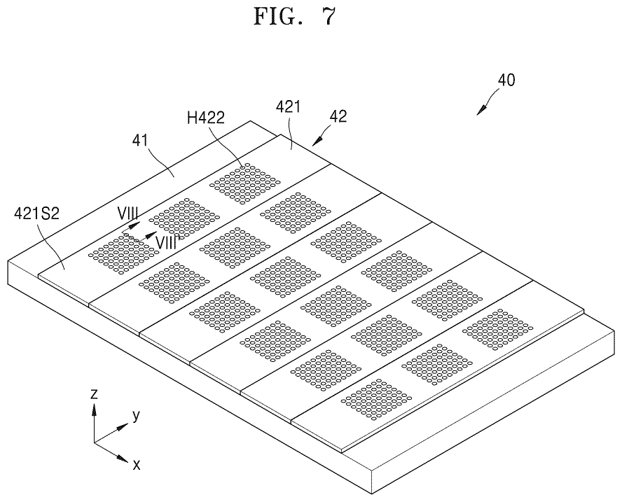

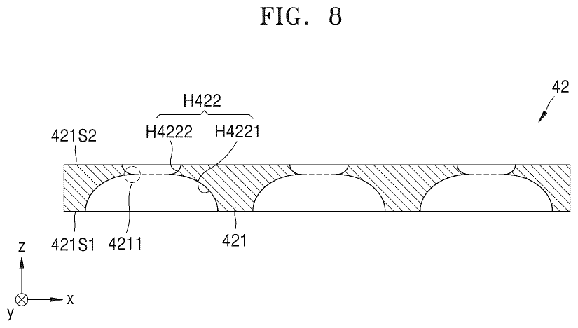

FIG. 3 is a schematic perspective view of a sheet frame 421 according to one or more embodiments. FIG. 4 is a schematic perspective view of the mask sheet 42 according to one or more embodiments. FIG. 5 is a schematic cross-sectional view of the mask sheet 42 according to one or more embodiments. FIG. 6 is an exploded perspective view of the mask assembly 40 according to one or more embodiments. FIG. 7 is a perspective view of the mask assembly 40 according to one or more embodiments. FIG. 8 is a schematic cross-sectional view of the mask sheet 42 according to one or more embodiments.

More specifically, FIG. 5 may correspond to a line V-V′ of FIG. 4, and FIG. 8 may correspond to a line VIII-VIII′ of FIG. 7.

Referring to FIGS. 2-8, the method 2 of manufacturing the mask assembly 40 may include an operation of fixing the mask sheet 42 to the mask frame 41 (in operation S1).

Referring to FIGS. 2 and 3, the sheet frame 421 may include a plurality of sheet frames 421, and the plurality of sheet frames 421 may be arranged along a first direction (e.g., a direction x). Each of the plurality of sheet frames 421 may extend in a second direction (e.g., a direction y) crossing the first direction (e.g., the direction x). For example, the sheet frame 421 may include an invar material.

Referring to FIGS. 2, 4, and 5, the sheet frame 421 may include a plurality of first deposition holes H422. That is, the mask sheet 42 may include the sheet frame 421 and the plurality of first deposition holes H422.

The sheet frame 421 may include a first surface 421S1 and a second surface 421S2 opposite to the first surface 421S1. Each of the plurality of first deposition holes H422 may include a 1st-1 deposition hole H4221 arranged in the first surface 421S1 of the sheet frame 421 and a 1st-2 deposition hole H4222 arranged in the second surface 421S2. The first deposition hole H422 may be symmetrical about a central axis CL. Each of the 1st-1 deposition hole H4221 and the 1st-2 deposition hole H4222 may be symmetrical about the central axis CL.

The 1st-1 deposition hole H4221 and the 1st-2 deposition hole H4222 may communicate with each other. A sum of a thickness D4221 of the 1st-1 deposition hole H4221 and a thickness D4222 of the 1st-2 deposition hole H4222 may be equal to a thickness D421 of the sheet frame 421.

Each of the 1st-1 deposition hole H4221 and the 1st-2 deposition hole H4222 may be formed by a photolithography process. For example, each of the 1st-1 deposition hole H4221 and the 1st-2 deposition hole H4222 may be formed by dry etching and/or wet etching.

The 1st-1 deposition hole H4221 may be formed as the sheet frame 421 is etched from the first surface 421S1 toward the second surface 421S2. Accordingly, a width W4221 of the 1st-1 deposition hole H4221 may gradually decrease from the first surface 421S1 toward the second surface 421S2. For example, the 1st-1 deposition hole H4221 may be concave from the first surface 421S1 toward the second surface 421S2.

The 1st-2 deposition hole H4222 may be formed as the sheet frame 421 is etched from the second surface 421S2 toward the first surface 421S1. Accordingly, a width W4222 of the 1st-2 deposition hole H4222 may gradually decrease from the second surface 421S2 toward the first surface 421S1. For example, the 1st-2 deposition hole H4222 may be concave from the second surface 421S2 toward the first surface 421S1.

Accordingly, in the operation of fixing the mask sheet 42 to the mask frame 41 (in operation S1), the sheet frame 421 may include a bump 4211 protruding toward the central axis CL of the first deposition hole H422. The bump 4211 may be arranged at a boundary between the 1st-1 deposition hole H4221 and the 1st-2 deposition hole H4222. With the bump 4211 as a boundary, the width W4221 of the 1st-1 deposition hole H4221 may gradually increase in a direction toward the first surface 421S1, and the width W4222 of the 1st-2 deposition hole H4222 may gradually increase in a direction toward the second surface 421S2.

The thickness D4221 of the 1st-1 deposition hole H4221 may be greater than the thickness D4222 of the 1st-2 deposition hole H4222. A maximum width of the 1st-1 deposition hole H4221 may be greater than a maximum width of the 1st-2 deposition hole H4222. That is, the 1st-1 deposition hole H4221 in contact with the first surface 421S1 may be wider than the 1st-2 deposition hole H4222 in contact with the second surface 421S2.

Referring to FIGS. 2 and 6-8, the mask sheet 42 may be fixed to the mask frame 41. That is, the mask assembly 40 may include the mask frame 41 and the mask sheet 42.

The mask frame 41 may support the mask sheet 42 and may include a frame opening OP41 therein. The mask frame 41 may be in the form of a picture frame in which the frame opening OP41 is arranged at the center. A length of one side (or a long side) of the mask frame 41 may be greater than a length of another side (or a short side) thereof. However, this is an example, and a shape of the mask frame 41 is not limited thereto.

The mask sheet 42 may be fixed to the mask frame 41 such that the first surface 421S1 of the sheet frame 421 faces the mask frame 41. The first surface 421S1 of the sheet frame 421 may be in contact with the mask frame 41.

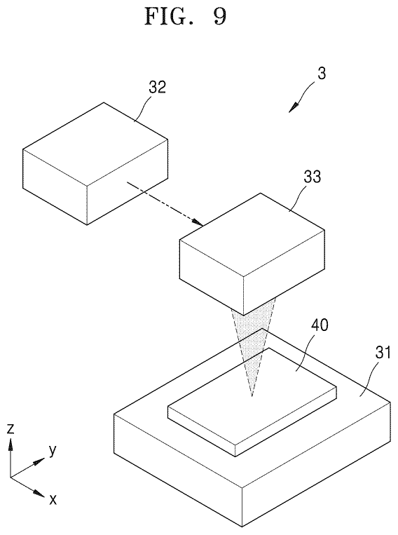

Accordingly, when the mask assembly 40 is arranged inside the chamber 10 (refer to FIG. 1) as shown in FIG. 1, the first surface 421S1 of the sheet frame 421 may face the deposition source 50 (refer to FIG. 1), and the second surface 421S2 of the sheet frame 421 may face the display substrate DS (refer to FIG. 1). Accordingly, the deposition material M (refer to FIG. 1) may sequentially pass through the frame opening OP41, the 1st-1 deposition hole H4221, and the 1st-2 deposition hole H4222 and may be deposited on the display substrate DS (refer to FIG. 1). However, due to the bump 4211 arranged at a boundary between the 1st-1 deposition hole H4221 and the 1st-2 deposition hole H4222, a shadow phenomenon may occur during the deposition process described above with reference to FIG. 1. Accordingly, the laser processing operation (in operation S2), which will be described with reference to FIGS. 9-13, may be additionally performed.

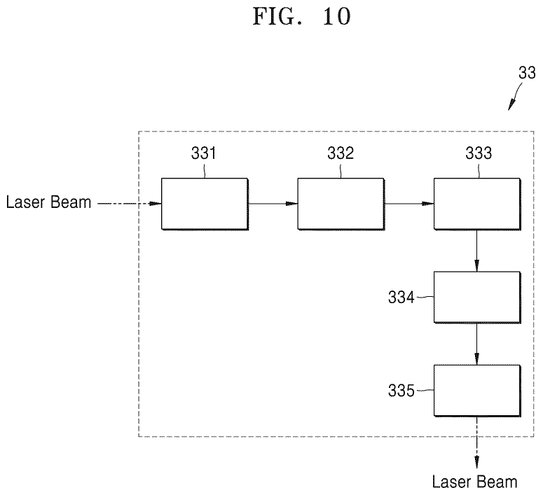

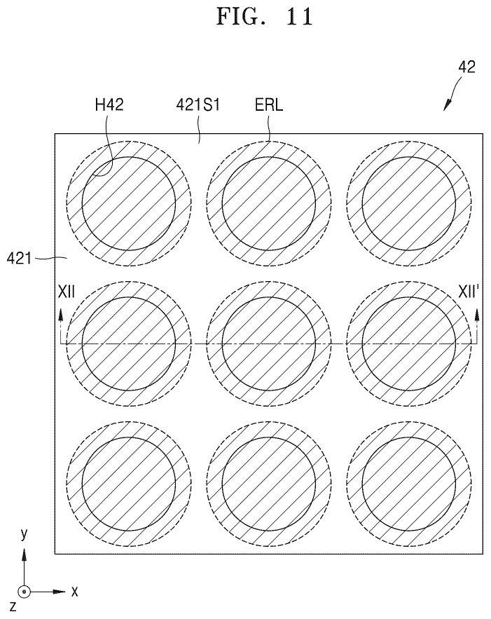

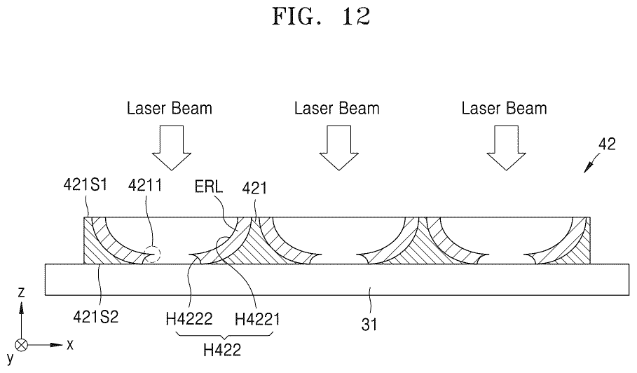

FIG. 9 is a schematic perspective view of a laser processing apparatus 3 according to one or more embodiments. FIG. 10 is a schematic block diagram of an optical unit 33 according to one or more embodiments. FIG. 11 is a schematic plan view of the mask sheet 42 according to one or more embodiments. FIG. 12 is a schematic cross-sectional view of the mask sheet 42 according to one or more embodiments. FIG. 13 is a schematic cross-sectional view of the mask sheet 42 according to one or more embodiments.

More specifically, FIGS. 12 and 13 may correspond to a line XII-XII′ of FIG. 11.

Referring to FIGS. 2 and 9-13, the method 2 of manufacturing the mask assembly 40 may include an operation of laser processing, by a laser processing apparatus, each of the plurality of first deposition holes H422 into a mask deposition hole H42 (in operation S2).

Referring to FIG. 9, the laser processing apparatus 3 may include a stage 31, a light source 32, and the optical unit 33.

The stage 31 may support the mask assembly 40. For example, the stage 31 may include an electrostatic chuck (ESC). Accordingly, the sheet frame 421 including an invar material may be stably seated on the stage 31. However, this is an example, and a structure of the stage 31 is not limited thereto.

The light source 32 may emit a laser beam. For example, the light source 32 may emit a femto laser beam. However, this is merely an example, and a laser beam emitted by the light source 32 is not limited thereto.

The optical unit 33 may adjust the laser beam emitted from the light source 32 to meet optical conditions for laser processing. The optical unit 33 may include at least one of a tuner 331, a beam splitter 332, a beam clipper 333, a scanner 334, and a telecentric F-θ lens 335. For example, the optical unit 33 may include all of the tuner 331, the beam splitter 332, the beam clipper 333, the scanner 334, and the telecentric F-θ lens 335. The laser beam emitted from the light source 32 may sequentially pass through the tuner 331, the beam splitter 332, the beam clipper 333, the scanner 334, and the telecentric F-θ lens 335 and may be irradiated onto the mask assembly 40 disposed on the stage 31.

The tuner 331 may finely adjust a location, power, and the number of irradiations of a laser beam. For example, the tuner 331 may include an acousto optic deflector. Because the laser beam passes through the tuner 331 before the beam splitter 332, the laser beam emitted from the light source 32 may be finely adjusted, and laser beams obtained by splitting via the beam splitter 332 may all move according to the laser beam finely adjusted by the tuner 331.

The beam splitter 332 may split the laser beam emitted from the light source 32 into a plurality of laser beams. Accordingly, the plurality of laser beams, instead of a single laser beam, may be concurrently (e.g., simultaneously) irradiated onto the mask assembly 40. Accordingly, the plurality of first deposition holes H422 may be laser processed concurrently (e.g., simultaneously).

The beam clipper 333 may selectively hide some of the plurality of laser beams obtained by splitting via the beam splitter 332 and adjust the number of laser beams to be used.

The scanner 334 may scan the plurality of laser beams onto the mask assembly 40 in one direction. For example, the scanner 334 may include a galvo scanner or a polygon scanner.

The telecentric F-θ lens 335 may adjust incidence angles of the plurality of laser beams to allow the laser beams to be perpendicularly (e.g., substantially perpendicularly) incident on the mask assembly 40.

Referring to FIGS. 2 and 9-13, the laser processing operation (in operation S2) may include an operation of seating the mask sheet 42 on the stage 31 (in operation S21), an operation of emitting, by the light source 32, a laser beam (in operation S22), and an operation of passing through, by the laser beam, the optical unit 33 to be incident toward the first surface 421S1 of the sheet frame 421 (in operation S23).

In the operation of seating the mask sheet 42 on the stage 31 (in operation S21), the second surface 421S2 of the sheet frame 421 may face the stage 31. Accordingly, the second surface 421S2 of the sheet frame 421 and the stage 31 may be in contact with each other.

As shown in FIGS. 11 and 12, in the operation of passing through, by the laser beam, the optical unit 33 to be incident toward the first surface 421S1 of the sheet frame 421 (in operation S23), an area of the sheet frame 421 that the laser beam reaches is referred to as a laser area ERL.

The laser area ERL may correspond to each of the plurality of first deposition holes H422. In a plan view, a size of the laser area ERL may be greater than a size of the first deposition hole H422. More specifically, the laser area ERL may overlap the bump 4211 of the sheet frame 421. Although FIG. 11 shows a plurality of laser areas ERL which are spaced (e.g., spaced apart) from each other, this is merely an example, and the plurality of laser areas ERL may overlap each other. Alternatively, one laser area ERL may overlap the plurality of first deposition holes H422.

As shown in FIGS. 12 and 13, as the laser beam is incident on the sheet frame 421, at least a portion of the sheet frame 421 may be removed. That is, the first deposition hole H422 may be processed into the mask deposition hole H42. Accordingly, as a result, the mask sheet 42 may include the sheet frame 421 and a plurality of mask deposition holes H42.

The plurality of mask deposition holes H42 may penetrate the sheet frame 421. That is, a thickness D42 of the plurality of mask deposition holes H42 may be the same as the thickness D421 of the sheet frame 421. A width W42 of each of the plurality of mask deposition holes H42 may gradually decrease from the first surface 421S1 of the sheet frame 421 toward the second surface 421S2. For example, each of the plurality of mask deposition holes H42 may be concave from the first surface 421S1 toward the second surface 421S2.

As the first deposition hole H422 is processed into the mask deposition hole H42, the bump 4211 of the sheet frame 421 may be removed. Accordingly, a shadow phenomenon that may occur in the deposition process described above with reference to FIG. 1 may be reduced. In addition, because the laser processing operation (in operation S2) is performed with the mask sheet 42 fixed to the mask frame 41, a 1 phenomenon in which unnecessary deformation occurs in the mask sheet 42 during the laser processing operation (in operation S2) may be reduced.

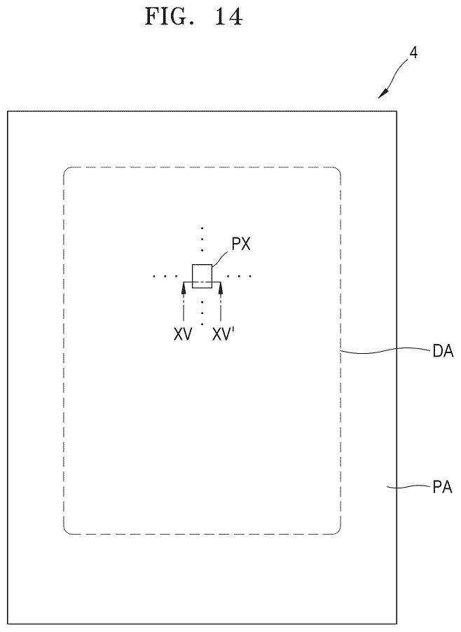

FIG. 14 is a schematic plan view of a display device 4 according to one or more embodiments.

Referring to FIG. 14, the display device 4 according to one or more embodiments may include a display area DA and a peripheral area PA located outside the display area DA along an edge or a periphery of the display area DA. The display device 4 may provide an image through an array of a plurality of pixels PX two-dimensionally arranged (e.g., along rows and columns of a matrix) in the display area DA.

The peripheral area PA is an area where no image is provided, and may entirely or partially be around (e.g., surround) the display area DA. A driver for providing an electrical signal or power to a pixel circuit corresponding to each of the pixels PX may be arranged in the peripheral area PA. A pad, which is an area to which an electronic element or a printed circuit board (PCB) may be electrically connected, may be arranged in the peripheral area PA.

Hereinafter, it is assumed that the display device 4 includes an organic light-emitting diode (OLED) as a light-emitting element, but the display device 4 described herein is not limited thereto. In another embodiment, the display device 4 may be a light-emitting display device including an inorganic light-emitting diode, that is, an inorganic light-emitting display. The inorganic light-emitting diode may include a PN junction diode including inorganic semiconductor-based materials. When a voltage is applied to the PN junction diode in a forward direction, holes and electrons are injected, and light of a certain color may be emitted by converting energy generated by recombination of the holes and electrons into light energy. The inorganic light-emitting diode described above may have a width of several to hundreds of micrometers, and in some embodiments, the inorganic light-emitting diode may be referred to as a micro LED. In another embodiment, the display device 4 may be a quantum dot light-emitting display.

The display device 4 may be used as the display screen of not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various products, such as a television, a notebook computer, a monitor, a billboard, and an Internet of things (IoT) device. In addition, the display device 4 according to one or more embodiments may be used in wearable devices, such as a smartwatch, a watch phone, a glasses-type display, and a head-mounted display (HMD). In addition, the display device 4 according to one or more embodiments may be used as a car's instrument panel, a center information display (CID) placed on a car's center fascia or dashboard, a room mirror display replacing a car's side mirror, or a display screen placed on the back of a front seat as entertainment for a car's rear seat.

FIG. 15 is a schematic cross-sectional view of the display device 4 according to one or more embodiments, and may correspond to a cross-section of the display device 4, taken along a line XV-XV′ of FIG. 14.

Referring to FIG. 15, the display device 4 may include a stacked structure of the substrate 100, a pixel circuit layer PCL, a display element layer DEL, and an encapsulation layer 300. The display substrate DS (refer to FIG. 1) described above may be the one being in the process of manufacturing the display device 4, for example, the one in which at least one of the pixel circuit layer PCL, the display element layer DEL, and the encapsulation layer 300 is stacked on the substrate 100.

The substrate 100 may have a multi-layer structure including a base layer and an inorganic layer, the base layer including polymer resin. For example, the substrate 100 may include a base layer including polymer resin, and a barrier layer of an inorganic insulating layer. For example, the substrate 100 may include a first base layer 101, a first barrier layer 102, a second base layer 103, and a second barrier layer 104 that are sequentially stacked on one another. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), and/or cellulose acetate propionate (CAP). The first barrier layer 102 and the second barrier layer 104 may include an inorganic insulating material, such as silicon oxide, silicon oxynitride and/or silicon nitride. The substrate 100 may be flexible.

The pixel circuit layer PCL is disposed on the substrate 100. FIG. 15 shows the pixel circuit layer PCL including a thin-film transistor TFT, and a buffer layer 111, a first gate insulating layer 112, a second gate insulating layer 113, an interlayer insulating layer 114, a first planarization insulating layer 115, and a second planarization insulating layer 116 disposed under and/or on elements of the thin-film transistor TFT.

The buffer layer 111 may reduce or prevent penetration of foreign materials, moisture, and/or external air from below the substrate 100 and may provide a flat surface on the substrate 100. The buffer layer 111 may include an inorganic insulating material, such as silicon oxide, silicon oxynitride and/or silicon nitride, and may have a single-layer or multi-layer structure including the above-described material.

The thin-film transistor TFT on the buffer layer 111 may include a semiconductor layer Act, and the semiconductor layer Act may include polysilicon. Alternatively, the semiconductor layer Act may include amorphous silicon, an oxide semiconductor, and/or an organic semiconductor. The semiconductor layer Act may include a channel region C, and a drain region D and a source region S respectively arranged on both sides of the channel region C. A gate electrode GE may overlap the channel region C in a thickness direction of the substrate 100.

The gate electrode GE may include a low-resistance metal material. The gate electrode GE may include a conductive material including molybdenum (Mo), aluminum (Al), copper (Cu), titanium (Ti), etc., and may have a multi-layer or single-layer structure including the above-described material.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) and/or zinc peroxide (ZnO₂).

The second gate insulating layer 113 may cover the gate electrode GE and may be disposed on the first gate insulating layer 112. Similar to the first gate insulating layer 112, the second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). The zinc oxide (ZnOₓ) may be zinc oxide (ZnO) and/or zinc peroxide (ZnO₂).

An upper electrode Cst2 of a storage capacitor Cst may be disposed on the second gate insulating layer 113. The upper electrode Cst2 may overlap the gate electrode GE below in the thickness direction of the substrate 100. In this regard, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

As described above, the storage capacitor Cst and the thin-film transistor TFT may overlap each other in the thickness direction of the substrate 100. In one or more embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layer or multi-layer structure including the above-described material.

The interlayer insulating layer 114 may cover the upper electrode Cst2 and may be disposed on the second gate insulating layer 113. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). The zinc oxide (ZnOₓ) may be zinc oxide (ZnO) and/or zinc peroxide (ZnO₂). The interlayer insulating layer 114 may have a single-layer or multi-layer structure including the above-described inorganic insulating material.

Each of the drain electrode DE and the source electrode SE may be on the interlayer insulating layer 114. The drain electrode DE and the source electrode SE may be respectively connected to the drain region D and the source region S through contact holes defined in the insulating layers below (e.g., a first gate insulating layer 112, a second gate insulating layer 113, an interlayer insulating layer 114). The drain electrode DE and the source electrode SE may include a highly conductive material. The drain electrode DE and the source electrode SE may include a conductive material including molybdenum (Mo), aluminum (AI), copper (Cu), titanium (Ti), etc., and may have a multi-layer or a single-layer structure including the above-described material. In one or more embodiments, the drain electrode DE and the source electrode SE may have a multi-layer structure of titanium (Ti)/aluminum (Al)/titanium (Ti).

The first planarization insulating layer 115 may cover the drain electrode DE and the source electrode SE and may be disposed on the interlayer insulating layer 114. The first planarization insulating layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

The second planarization insulating layer 116 may be disposed on the first planarization insulating layer 115. The second planarization insulating layer 116 may include the same material as that of the first planarization insulating layer 115, and may include an organic insulating material, such as a general commercial polymer, such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

The display element layer DEL may be disposed on the pixel circuit layer PCL having the above-described structure. The display element layer DEL may include an organic light-emitting diode OLED as a display element (that is, a light-emitting element), and the organic light-emitting diode OLED may include a stacked structure of a pixel electrode 210, an intermediate layer 220, and a common electrode 230. The organic light-emitting diode OLED, for example, may emit red, green, or blue light, or may emit red, green, blue, or white light. The organic light-emitting diode OLED may emit light through an emission area, and the emission area may be defined as the pixel PX.

The pixel electrode 210 of the organic light-emitting diode OLED may be on the second planarization insulating layer 116 and electrically connected to the thin-film transistor TFT through contact holes defined in the second planarization insulating layer 116 and the first planarization insulating layer 115 and a contact metal CM disposed on the first planarization insulating layer 115.

The pixel electrode 210 may include conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 210 may include a reflection layer including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In another embodiment, the pixel electrode 210 may further include a layer formed of ITO, IZO, ZnO, and/or In₂O₃ on/under the above-described reflection layer.

A pixel-defining layer 117 including an opening 117OP exposing a central portion of the pixel electrode 210 may be disposed on the pixel electrode 210. The pixel-defining layer 117 may include an organic insulating material and/or an inorganic insulating material. The opening 117OP may define an emission area of light emitted from the organic light-emitting diode OLED. For example, a size/width of the opening 117OP may correspond to a size/width of the emission area. Accordingly, a size and/or width of the pixel PX may depend on a size and/or width of the corresponding opening 117OP of the pixel-defining layer 117.

The intermediate layer 220 may include an emission layer 222 corresponding to the pixel electrode 210. The emission layer 222 may include a polymer organic material and/or low-molecular weight organic material emitting light of a certain color. Alternatively, the emission layer 222 may include an inorganic light-emitting material and/or quantum dots.

In one or more embodiments, the intermediate layer 220 may include a first functional layer 221 and a second functional layer 223 disposed under and on the emission layer 222, respectively. The first functional layer 221 may include, for example, a hole transport layer (HTL), or an HTL and a hole injection layer (HIL). The second functional layer 223 is an element disposed on the emission layer 222, and may include an electron transport layer (ETL) and/or an electron injection layer (EIL). Like the common electrode 230 described below, the first functional layer 221 and/or the second functional layer 223 may be a common layer entirely covering the substrate 100.

The common electrode 230 may be disposed over the pixel electrode 210 and may overlap the pixel electrode 210 in the thickness direction of the substrate 100. The common electrode 230 may include a conductive material having a low work function. For example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. Alternatively, the common electrode 230 may further include a layer, such as ITO, IZO, ZnO, and/or In₂O₃, on a (semi) transparent layer including the above-described material. The common electrode 230 may be a single electrode entirely covering the substrate 100.

The encapsulation layer 300 may be disposed on the display element layer DEL and may cover the display element layer DEL. The encapsulation layer 300 may include at least one inorganic encapsulation layer and at least one organic encapsulation layer, and as an example embodiment, FIG. 15 shows the encapsulation layer 300 including a first inorganic encapsulation layer 310, an organic encapsulation layer 320, and a second inorganic encapsulation layer 330 that are sequentially stacked on one another.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and/or silicon oxynitride. The organic encapsulation layer 320 may include a polymer-based material. Examples of the polymer-based material may include acryl-based resin, epoxy-based resin, polyimide, and polyethylene. In one or more embodiments, the organic encapsulation layer 320 may include acrylate. The organic encapsulation layer 320 may be formed by curing a monomer or coating with a polymer. The organic encapsulation layer 320 may have transparency.

In one or more embodiments, a touch sensor layer may be disposed on the encapsulation layer 300, and an optical functional layer may be disposed on the touch sensor layer. The touch sensor layer may obtain coordinate information according to an external input, for example, a touch event. The optical functional layer may decrease reflectance of light (external light) incident from the outside toward a display device and/or may improve color purity of light emitted from the display device. In one or more embodiments, the optical functional layer may include a phase retarder and/or a polarizer. The phase retarder may be of a film type or a liquid crystal coating type and may include λ/2 phase retarder and/or a λ/4 phase retarder. The polarizer may also be of a film type or a liquid crystal coating type. The film type may include an elongated synthetic resin film, and the liquid crystal coating type may include liquid crystals arranged in a certain arrangement. The phase retarder and the polarizer may further include a protection film.

An adhesive member may be disposed between the touch sensor layer and the optical functional layer. As the adhesive member, a general one known in the art (e.g., a suitable adhesive member known to a person of ordinary skill in the art) may be employed without limitation. The adhesive member may be a pressure-sensitive adhesive (PSA).

The deposition material M described with reference to FIGS. 1-13 may include the intermediate layer 220 described with reference to FIG. 15. For example, the deposition material M (refer to FIG. 1) may include the emission layer 222.

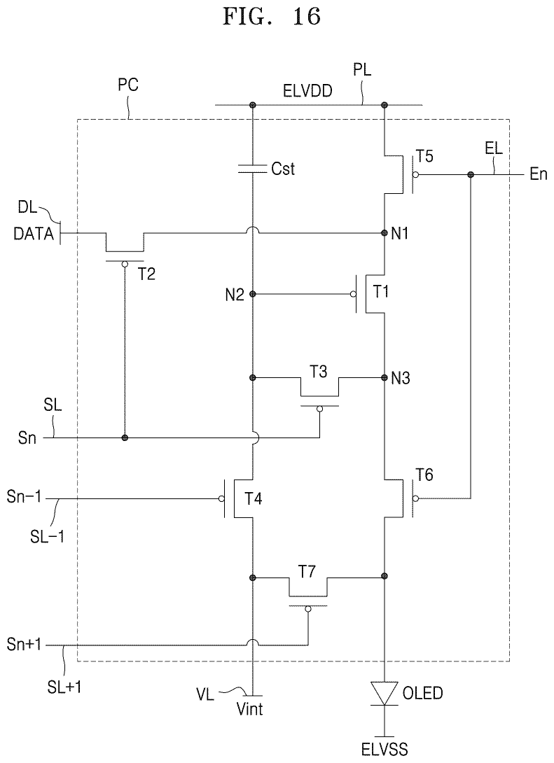

FIG. 16 is an equivalent circuit diagram of a pixel PX according to one or more embodiments.

Referring to FIG. 16, a pixel circuit PC may include first to seventh transistors T1 to T7, and depending on the type (p-type or n-type) and/or operation conditions of a transistor, a first terminal of each of the first to seventh transistors T1 to T7 may be a source terminal or a drain terminal, and a second terminal thereof may be a terminal different from the first terminal. For example, when the first terminal is a source terminal, the second terminal may be a drain terminal.

The pixel circuit PC may be connected to a first scan line SL configured to transmit a first scan signal Sn, a second scan line SL−1 configured to transmit a second scan signal Sn−1, a third scan line SL+1 configured to transmit a third scan signal Sn+1, an emission control line EL configured to transmit an emission control signal En, a data line DL configured to transmit a data signal DATA, a driving voltage line PL configured to transfer a driving voltage ELVDD, and an initialization voltage line VL configured to transfer an initialization voltage Vint.

The first transistor T1 includes a gate terminal connected to a second node N2, a first terminal connected to a first node N1, and a second terminal connected to a third node N3. The first transistor T1 serves as a driving transistor and is configured to receive the data signal DATA according to a switching operation of the second transistor T2 and supply a driving current to a light-emitting element. The light-emitting element may be the organic light-emitting diode OLED.

The second transistor T2 (e.g., a switching transistor) includes a gate terminal connected to the first scan line SL, a first terminal connected to the data line DL, and a second terminal connected to the first node N1 (or the first terminal of the first transistor T1). The second transistor T2 may be turned on according to the first scan signal Sn received through the first scan line SL to perform a switching operation for transmitting the data signal DATA transmitted to the data line DL to the first node N1.

The third transistor T3 (e.g., a compensation transistor) includes a gate terminal connected to the first scan line SL, a first terminal connected to the second node N2 (or the gate terminal of the first transistor T1), and a second terminal connected to the third node N3 (or the second terminal of the first transistor T1). The third transistor T3 may be turned on according to the first scan signal Sn received through the first scan line SL to diode-connect the first transistor T1. The third transistor T3 may have a structure in which two or more transistors are connected in series.

The fourth transistor T4 (e.g., a first initialization transistor) includes a gate terminal connected to the second scan line SL−1, a first terminal connected to the initialization voltage line VL, and a second terminal connected to the second node N2.

The fourth transistor T4 may be turned on according to the second scan signal Sn−1 received through the second scan line SL−1 to transfer the initialization voltage Vint to the gate terminal of the first transistor T1 and initialize a gate voltage of the first transistor T1. The fourth transistor T4 may have a structure in which two or more transistors are connected in series.

The fifth transistor T5 (e.g., a first emission control transistor) includes a gate terminal connected to the emission control line EL, a first terminal connected to the driving voltage line PL, and a second terminal connected to the first node N1. The sixth transistor T6 (e.g., a second emission control transistor) includes a gate terminal connected to the emission control line EL, a first terminal connected to the third node N3, and a second terminal connected to a pixel electrode of the organic light-emitting diode OLED. The fifth transistor T5 and the sixth transistor T6 are concurrently (e.g., simultaneously) turned on according to the emission control signal En received through the emission control line EL, and thus, current flows through the organic light-emitting diode OLED.

The seventh transistor T7 (e.g., a second initialization transistor) includes a gate terminal connected to the third scan line SL+1, a first terminal connected to the second terminal of the sixth transistor T6 and the pixel electrode of the organic light-emitting diode OLED, and a second terminal connected to the initialization voltage line VL. The seventh transistor T7 may be turned on according to the third scan signal Sn+1 received through the third scan line SL+1 to transfer the initialization voltage Vint to the pixel electrode of the organic light-emitting diode OLED and initialize a voltage of the pixel electrode of the organic light-emitting diode OLED. The seventh transistor T7 may be omitted.

The storage capacitor Cst includes a first electrode connected to the second node N2 and a second electrode connected to the driving voltage line PL.

The organic light-emitting diode OLED may include a pixel electrode and an opposite electrode facing the pixel electrode, and the opposite electrode may receive a common voltage ELVSS. The organic light-emitting diode OLED may receive a driving current from the first transistor T1 and thus may emit light in a certain color, thereby displaying an image. The opposite electrode may be common to, that is, provided as a single electrode for, a plurality of pixels.

According to one or more of the above embodiments, deposition quality may be improved in a deposition process for depositing a deposition material on a display substrate.

Effects of one or more embodiments are not limited thereto, and other unmentioned effects will be apparent to one of ordinary skill in the art from the following claims and their equivalents.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing a mask assembly, the method comprising:
fixing a mask sheet to a mask frame, wherein the mask sheet comprises a sheet frame and a plurality of first deposition holes penetrating the sheet frame; and
laser processing, by a laser processing apparatus, the plurality of first deposition holes into a plurality of mask deposition holes penetrating the sheet frame, respectively,
wherein each of the plurality of first deposition holes comprises:
a 1st-1 deposition hole in a first surface of the sheet frame; and
a 1st-2 deposition hole in a second surface of the sheet frame opposite to the first surface and communicating with the 1st-1 deposition hole,
wherein a width of each of the plurality of mask deposition holes gradually decreases from the first surface of the sheet frame toward the second surface of the sheet frame.

2. The method of claim 1, wherein a thickness of each of the plurality of mask deposition holes is same as a thickness of the sheet frame.

3. The method of claim 1, wherein each of the plurality of mask deposition holes is concave from the first surface toward the second surface.

4. The method of claim 1, wherein a width of the 1st-1 deposition hole gradually decreases from the first surface of the sheet frame toward the second surface, and a width of the 1st-2 deposition hole gradually decreases from the second surface of the sheet frame toward the first surface.

5. The method of claim 4, wherein a sum of a thickness of the 1st-1 deposition hole and a thickness of the 1st-2 deposition hole is equal to a thickness of the sheet frame.

6. The method of claim 4, wherein the 1st-1 deposition hole is concave from the first surface toward the second surface, and the 1st-2 deposition hole is concave from the second surface toward the first surface.

7. The method of claim 4, wherein, in the fixing of the mask sheet to the mask frame, the sheet frame comprises a bump protruding toward a central axis of the first deposition hole at a boundary between the 1st-1 deposition hole and the 1st-2 deposition hole.

8. The method of claim 1, wherein the 1st-1 deposition hole is thicker than the 1st-2 deposition hole.

9. The method of claim 1, wherein the laser processing comprises:
seating the mask sheet on a stage such that the second surface faces the stage; emitting, by a light source, a laser beam that passes through an optical unit and is incident on the first surface.

10. The method of claim 9, wherein the light source comprises at least one of a tuner, a beam splitter, a beam clipper, a scanner, or a telecentric F-θ lens.

11. A method of manufacturing a mask assembly, the method comprising:
fixing a mask sheet to a mask frame, wherein the mask sheet comprises a sheet frame and a plurality of first deposition holes penetrating the sheet frame; and
laser processing, by a laser processing apparatus, the plurality of first deposition holes into a plurality of mask deposition holes penetrating the sheet frame, respectively,
wherein each of the plurality of first deposition holes comprises:
a 1st-1 deposition hole in a first surface of the sheet frame; and
a 1st-2 deposition hole in a second surface of the sheet frame opposite to the first surface and communicating with the 1st-1 deposition hole,
wherein a width of the 1st-1 deposition hole gradually decreases from the first surface of the sheet frame toward the second surface, and a width of the 1st-2 deposition hole gradually decreases from the second surface of the sheet frame toward the first surface.

12. The method of claim 11, wherein a sum of a thickness of the 1st-1 deposition hole and a thickness of the 1st-2 deposition hole is equal to a thickness of the sheet frame.

13. The method of claim 11, wherein the 1st-1 deposition hole is concave from the first surface toward the second surface, and the 1st-2 deposition hole is concave from the second surface toward the first surface.

14. The method of claim 11, wherein, in the fixing of the mask sheet to the mask frame, the sheet frame comprises a bump protruding toward a central axis of the first deposition hole at a boundary between the 1st-1 deposition hole and the 1st-2 deposition hole.

15. The method of claim 11, wherein a width of each of the plurality of mask deposition holes gradually decreases from the first surface of the sheet frame toward the second surface.

16. The method of claim 15, wherein a thickness of each of the plurality of mask deposition holes is same as a thickness of the sheet frame.

17. The method of claim 15, wherein each of the plurality of mask deposition holes is concave from the first surface toward the second surface.

18. The method of claim 11, wherein the 1st-1 deposition hole is thicker than the 1st-2 deposition hole.

19. The method of claim 11, wherein the laser processing comprises:
seating the mask sheet on a stage such that the second surface faces the stage;
emitting, by a light source, a laser beam that passes through an optical unit and is incident on the first surface.

20. The method of claim 19, wherein the light source comprises at least one of a tuner, a beam splitter, a beam clipper, a scanner, or a telecentric F-θ lens.
